(19) United States
(12) Patent Application Publication
(10) Pub. No.: US 2014/0346534 A1
(43) Pub. Date: Nov. 27, 2014

(54) PIXEL UNIT AND AN ARRAY SUBSTRATE

(71) Applicants: Xiaohui Yao, Shenzhen City (CN); Jingfeng Xue, Shenzhen City (CN); Je-hao Hsu, Shenzhen City (CN)

(72) Inventors: Xiaohui Yao, Shenzhen City (CN); Jingfeng Xue, Shenzhen City (CN); Je-hao Hsu, Shenzhen City (CN)

(73) Assignee: Shenzhen China Star Optoelectronics Technology Co., Ltd., Shenzhen, Guangdong (CN)

(21) Appl. No.: 13/985,693

(22) PCT Filed: Jun. 27, 2013
(86) PCT No.: PCT/CN2013/078169

§ 371 Date: Aug. 15, 2013

(30) Foreign Application Priority Data
May 24, 2013 (CN) 201310198557.6

(51) Int. Cl. H01L 27/12

(52) U.S. Cl. CPC H01L 27/124
USPC 257/88

(57) ABSTRACT

A pixel unit and an array substrate are provided. The pixel unit includes a scan line extended along a first extension direction; a data line extended along a second extension direction; a solder pad electrically connects to the scan line and the data line; an insulation layer covering the scan line and the data line, and having a through hole; and multiple strip electrodes disposed on the insulation layer and extending along a third extension direction, wherein, the multiple strip electrodes electrically connect to the solder pad by the through hole. The solder pad and the multiple strip electrodes are all made of a transparent conductive material. A shape of the solder pad is a polygon and is parallel to the third extension direction. The present invention can effectively suppress the “dark fringes” phenomenon around the solder pad.

### BACKGROUND OF THE INVENTION

1. Field of the Invention

The present invention relates to the LCD technology, and more particular to a pixel unit and an array substrate.

2. Description of Related Art

LCD is the mainstream of the display technology. The LCD device comprises a pair of substrates and a liquid crystal layer interposed between the pair of substrates. The substrates are provided with electrodes for generating electric field, such as pixel electrodes and common electrodes. By applying voltage to the two substrates, it will generate an electric field at the liquid crystal layer. A direction of the electric field determines an arrangement direction of the liquid crystal molecules. By adjusting the voltage, the arrangement direction of the liquid crystal molecules will change such that a light which enters the liquid crystal layer will produce polarization, and the LCD device can display an image.

In order to increase a viewing angle of the LCD device, the pixel electrodes in the LCD device are usually designed with multiple strip electrodes which are parallel with each other and spaced apart. The strip electrodes are divided into several parts, and each part of the strip electrodes extends in different directions. The pixel electrode becomes a “ [symbol] ” shape or a “ [symbol] ” shape structure. For example, with reference to FIG. 1, FIG. 1 is a schematic drawing of a pixel unit of a LCD device in the prior art. The LCD device includes a scan line G1, a data line D1, a solder pad 110 and multiple strip electrodes 120. The scan line G1 and the data line D1 are perpendicular with each other, and the solder pad 110 is formed at an intersection location of the scan line G1 and the data line D1. The solder pad 110 is generally rectangular. The scan line G1 and the data lines D1 are connected to the solder pad 110 by wires. The several strip electrodes 120 are parallel with each other and space apart. The multiple strip electrodes 120, the scan line G1, the data line D1, and the solder pad 110 are in different layers, and the different layers are insulated. The multiple strip electrodes 120 are connected to the below solder pad 110 by a through hole 101.

In the prior art, it only consider that the electric field generated by the strip electrodes 120 will affect the arrangement of the liquid crystal molecules. However, because the solder pad 110 and the strip electrodes 120 are all made of a transparent conductive material such as ITO (Indium Tin Oxide). Therefore, the solder pad 110 will also generate an electric field. Because an edge of the solder pad 110 is crossing to the direction of the strip electrodes 120, the electric field generated at the edge of the solder pad 110 will affect the electric field generated by the strip electrodes 120 so as to cause the chaos of the arrangement of the liquid crystal molecules. Please refer to FIG. 1, FIG. 2 and FIG. 3, wherein, FIG. 2 is a schematic drawing of the arrangement of liquid crystal molecules corresponding to the pixel unit shown in FIG. 1, FIG. 3 is a schematic drawing of an optical simulation image of the pixel unit shown in FIG. 1. As shown in FIG. 2, areas A1 and A2 are the areas corresponding to the edge of the solder pad 110. It can be known from FIG. 2, except at the areas A1 and A2, the liquid crystal molecules at the remaining areas have substantially the same arrangement direction. As shown in FIG. 3, an area B1 corresponds to the area A1, and an area B2 corresponds to the area A2. A shadow C represents the solder pad 110. From FIG. 3, expect the areas B1 and B2, the light transmittance at the remaining areas are higher. Because the affection of the electric field of the solder pad 110, the light transmittance at the areas B1 and B2 are lower, and this phenomenon is called “dark fringes” phenomenon.

### SUMMARY OF THE INVENTION

The main object of the present invention is to provide a pixel unit and an array substrate to reduce the electric field of strip electrodes being affected.

In order to solve the above technical problems, a technical solution provided by the present invention is: A pixel unit comprising: a scan line extended along a first extension direction; a data line extended along a second extension direction, wherein, the first extension direction is intersected with the second extension direction; a solder pad formed at an intersection location of the scan line and the data line, and the solder pad electrically connects to the scan line and the data line; an insulation layer covering the scan line and the data line, and having a through hole; and multiple strip electrodes parallel with each other and spaced apart, and disposed on the insulation layer and extending along a third extension direction, wherein, the third extension direction and the first extension direction form a predetermined angle, and the multiple strip electrodes electrically connect to the solder pad by the through hole; wherein, the solder pad and the multiple strip electrodes are all made of a transparent conductive material; a shape of the solder pad is a quadrilateral with at least a pair of parallel opposite sides; the at least a pair of parallel opposite sides of the solder pad is parallel to the third extension direction; a shape of the through hole is a quadrilateral with at least a pair of parallel opposite sides; the at least a pair of parallel opposite sides of the through hole is parallel to the third extension direction; the first extension direction and the second extension direction are perpendicular.

Wherein, the pixel unit further comprises a thin film transistor, wherein, the thin film transistor located at the intersection location of the scan line and the data line, and a gate electrode of the thin film transistor is electrically connected to the scan line, a source electrode is electrically connected to the data line, and a drain electrode is electrically connected to the solder pad.

Wherein, the predetermined angle is 45 degrees.

Wherein, the transparent conductive material is indium tin oxide.

Wherein, the multiple strip electrodes are spaced apart with the same spacing.

In order to solve the above technical problems, another technical solution provided by the present invention is: a pixel unit comprising: a scan line extended along a first extension direction; a data line extended along a second extension direction, wherein, the first extension direction is intersected with the second extension direction; a solder pad formed at an intersection location of the scan line and the data line, and the solder pad electrically connects to the scan line and the data line; an insulation layer covering the scan line and the data line, and having a through hole; and multiple strip electrodes parallel with each other and spaced apart, and disposed on the insulation layer and extending along a third extension direction, wherein, the third extension direction and the first extension direction form a predetermined angle, and the multiple strip electrodes electrically connect to the solder pad by the through hole; wherein, the solder pad and the multiple strip electrodes are all made of a transparent conductive material; a shape of the solder pad is a polygon; at least one side of the solder pad is parallel to the third extension direction.

Wherein, the pixel unit further comprises a thin film transistor, wherein, the thin film transistor located at the intersection location of the scan line and the data line, and a gate electrode of the thin film transistor is electrically connected to the scan line, a source electrode is electrically connected to the data line, and a drain electrode is electrically connected to the solder pad.

Wherein, the shape of the solder pad is a quadrilateral with at least a pair of parallel opposite sides, and the at least a pair of parallel opposite sides of the solder pad is parallel to the third extension direction.

Wherein, a shape of the through hole is a polygon; at least one side of the through hole is parallel to the third extension direction.

Wherein, the shape of the through hole is a quadrilateral with at least a pair of parallel opposite sides, and the at least a pair of parallel opposite sides of the through hole is parallel to the third extension direction.

Wherein, the first extension direction and the second extension direction are perpendicular.

Wherein, the predetermined angle is 45 degrees.

Wherein, the transparent conductive material is indium tin oxide.

Wherein, the multiple strip electrodes are spaced apart with the same spacing.

In order to solve the above technical problems, another technical solution provided by the present invention is: an array substrate comprising: a glass substrate; and a pixel unit disposed on the glass substrate, the pixel unit comprising: a scan line extended along a first extension direction; a data line extended along a second extension direction, wherein, the first extension direction is intersected with the second extension direction; a solder pad formed at an intersection location of the scan line and the data line, and the solder pad electrically connects to the scan line and the data line, an insulation layer covering the scan line and the data line, and having a through hole; and multiple strip electrodes parallel with each other and spaced apart, and disposed on the insulation layer and extending along a third extension direction, wherein, the third extension direction and the first extension direction form a predetermined angle, and the multiple strip electrodes electrically connect to the solder pad by the through hole; wherein, the solder pad and the multiple strip electrodes are all made of a transparent conductive material; a shape of the solder pad is a polygon; at least one side of the solder pad is parallel to the third extension direction.

Wherein, the pixel unit further comprises a thin film transistor, wherein, the thin film transistor located at the intersection location of the scan line and the data line, and a gate electrode of the thin film transistor is electrically connected to the scan line, a source electrode is electrically connected to the data line, and a drain electrode is electrically connected to the solder pad.

Wherein, the shape of the solder pad is a quadrilateral with at least a pair of parallel opposite sides, and the at least a pair of parallel opposite sides of the solder pad is parallel to the third extension direction.

Wherein, a shape of the through hole is a polygon; at least one side of the through hole is parallel to the third extension direction.

Wherein, the shape of the through hole is a quadrilateral with at least a pair of parallel opposite sides, and the at least a pair of parallel opposite sides of the through hole is parallel to the third extension direction.

Wherein, the first extension direction and the second extension direction are perpendicular.

Through the above way, in the pixel unit and the array substrate of the present invention, at least one side of the solder pad is parallel to the extension direction of the strip electrodes so that the at least one side of the solder pad does not affect the electric field of at least one side of the field strip electrodes. The impact of the electric field of the strip electrodes can be reduced so as to effectively suppress the “dark fringes” phenomenon around the solder pad and to enhance the display quality.

### BRIEF DESCRIPTION OF THE DRAWINGS

FIG. 1 is a schematic drawing of a pixel unit of a LCD device in the prior art;

FIG. 2 is a schematic drawing of the arrangement of liquid crystal molecules corresponding to the pixel unit shown in FIG. 1;

FIG. 3 is a schematic drawing of an optical simulation image of the pixel unit shown in FIG. 1;

FIG. 4 is a schematic drawing of a pixel unit according to a first embodiment of the present invention;

FIG. 5 is a schematic drawing of the arrangement of liquid crystal molecules corresponding to the pixel unit shown in FIG. 4;

FIG. 6 is a schematic drawing of an optical simulation image of the pixel unit shown in FIG. 4; and

FIG. 7 is a schematic drawing of a pixel unit according to a second embodiment of the present invention.

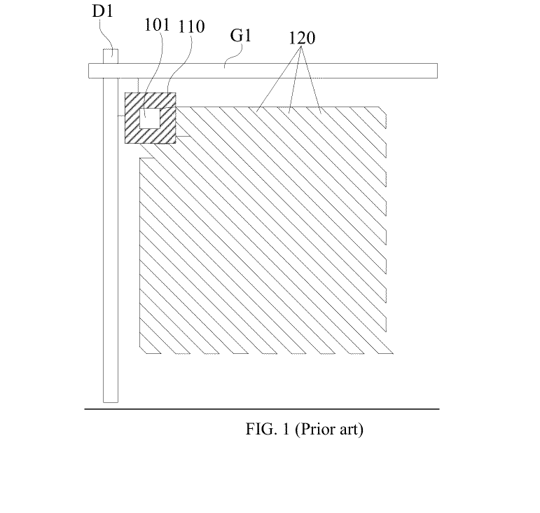

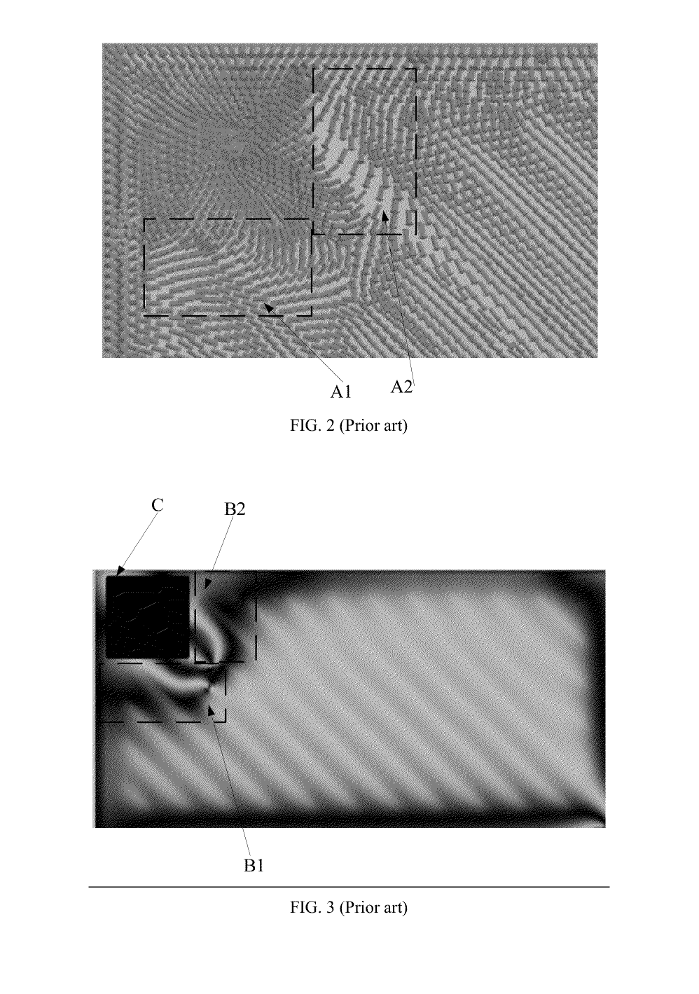

### DETAILED DESCRIPTION OF THE PREFERRED EMBODIMENT

The following content combines with the drawings and the embodiment for describing the present invention in detail. It is obvious that the following embodiments are only some embodiments of the present invention. For the skilled persons of ordinary skill in the art without creative effort, the other embodiments obtained thereby are still covered by the present invention.

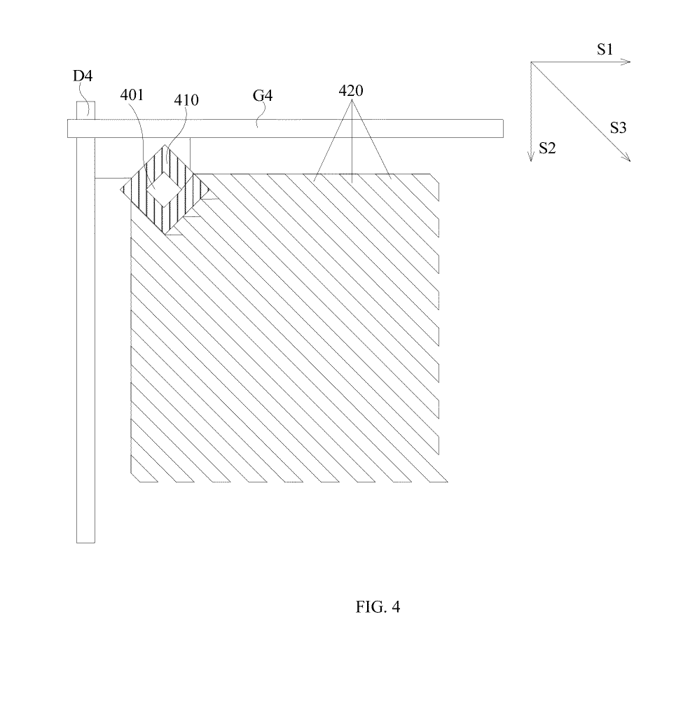

With reference to FIG. 4, FIG. 4 is a schematic drawing of a pixel unit according to a first embodiment of the present invention. A pixel unit includes a scan line G4, a data line D4, a solder pad 410, an insulation layer (not shown) and multiple strip electrodes 420.

The scan line G4 extends along a first extension direction S1, and the data line D4 extends along a second extension direction S2. The first extension direction S1 is intersected with the second extension direction S2. Preferably, the first extension direction S1 and the second extension direction S2 are perpendicular.

The solder pad 410 is formed at the intersection location of the scan line G4 and the data line D4. The solder pad 410 electrically connects to the scan line G4 and the data line D4, for example, by a wire connection. An insulation layer covers the scan line G4, the data line D4, and the solder pad 410, and the insulation layer has a through hole 401.

The multiple strip electrodes 420 are parallel with each other and spaced apart. Preferably, the multiple strip electrodes 420 are spaced apart with the same spacing. The multiple strip electrodes 420 are disposed on the insulation layer and extending along a third extension direction S3. The third extension direction S3 and the first extension direction S1 form a predetermined angle. Preferably, the predetermined angle is 45 degrees. The multiple strip electrodes 420 electrically connect to the solder pad 410 by the through hole 401, for example, by wire connections.

The solder pad 410 and the multiple strip electrodes 420 are all made of a transparent conductive material. Preferably, the transparent conductive material is indium tin oxide. The shape of the solder pad 410 is a polygon. At least one side of the solder pad 410 is parallel to the third extension direction S3. Furthermore, the solder pad 410 may be a quadrilateral with at least a pair of parallel opposite sides. At least a pair of opposite sides of the solder pad 410 is parallel to the third extension direction S3. In this embodiment, the solder pad 410 is a rectangle. In another embodiment, the solder pad 410 could also a trapezoid or a diamond shape.

Because at least one side of the solder pad 410 is parallel to the third extension direction S3, a direction of the electric field of the side of the solder pads 410 is the same with a direction of the electric field of the strip electrode 420 in order to reduce the affection of the solder pad 410 to the electric field of the strip electrodes 420. The “dark fringes” phenomenon around the solder pad 410 can be effectively suppressed so as to improve the display quality.

In the present embodiment, the strip electrodes 420 connect to the data line D4 by the solder pad 410. Therefore, the pixel unit is utilized a passive drive method. When the scan line G4 and the data line D4 input driving voltage synchronously, it will synthesis a driving waveform on the strip electrodes 420 in order to guide the liquid crystal molecules to arrange.

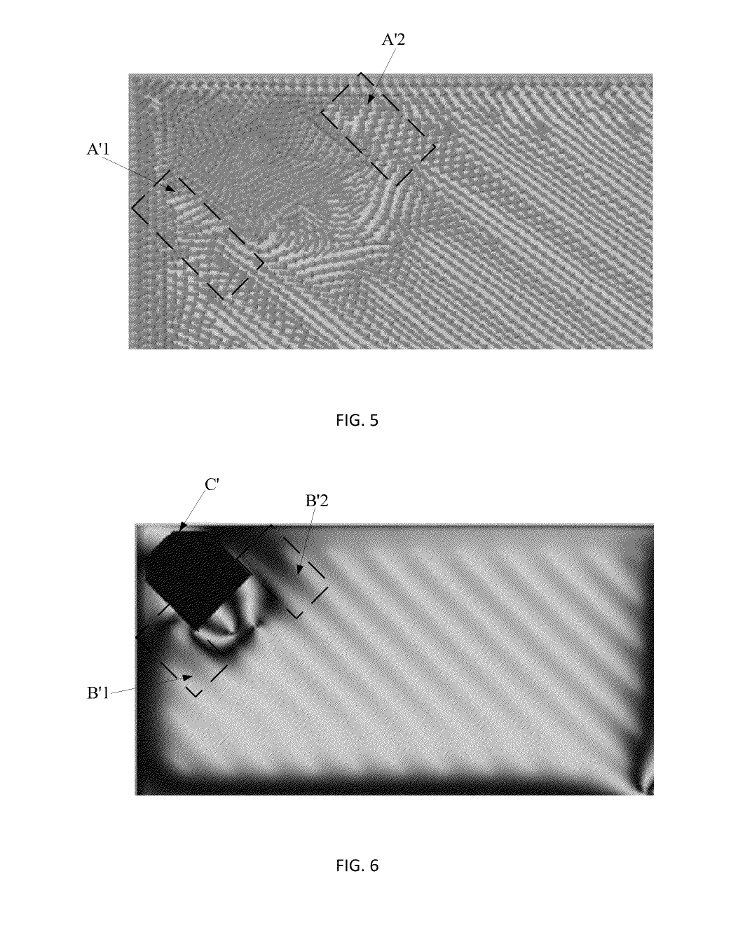

With reference to FIG. 4, FIG. 5 and FIG. 6, wherein, FIG. 5 is a schematic drawing of the arrangement of liquid crystal molecules corresponding to the pixel unit shown in FIG. 4; FIG. 6 is a schematic drawing of an optical simulation image of the pixel unit shown in FIG. 4. In FIG. 5, the areas A′1 and A′2 are areas near the pair of the opposite sides of the solder pad 410 which are parallel to the third extension direction S3. In these two areas, the change in the arrangement direction of the liquid crystal molecules is small, and is substantially consistent with the remaining areas of the arrangement direction of the liquid crystal molecules. In FIG. 6, an area B′1 corresponds to the area A′1, and an area B′2 corresponds to an area A′2, and a shadow C′ represents the solder pad 410. In both areas, comparing to the remaining areas, the light transmittance is not decrease significantly. Therefore, it indicates that “dark fringes” phenomenon has been effectively suppressed.

With reference again to FIG. 4, because the through hole 401 is electrically conductive, and it require to ensure a certain distance between the edge 410 of the through hole 401 and the edge of the solder pad 410, so that, in the present embodiment, the through hole 401 is also a polygon. At least one side of the through hole 401 is parallel to the third extension direction S3. In particular, the shape of the through hole 401 and the shape of the solder pad 410 are the same. The shape of the through hole 401 is a quadrilateral shape with at least a pair of parallel opposite sides. At least a pair of opposite sides of the through hole 401 is parallel to the third extension direction S3.

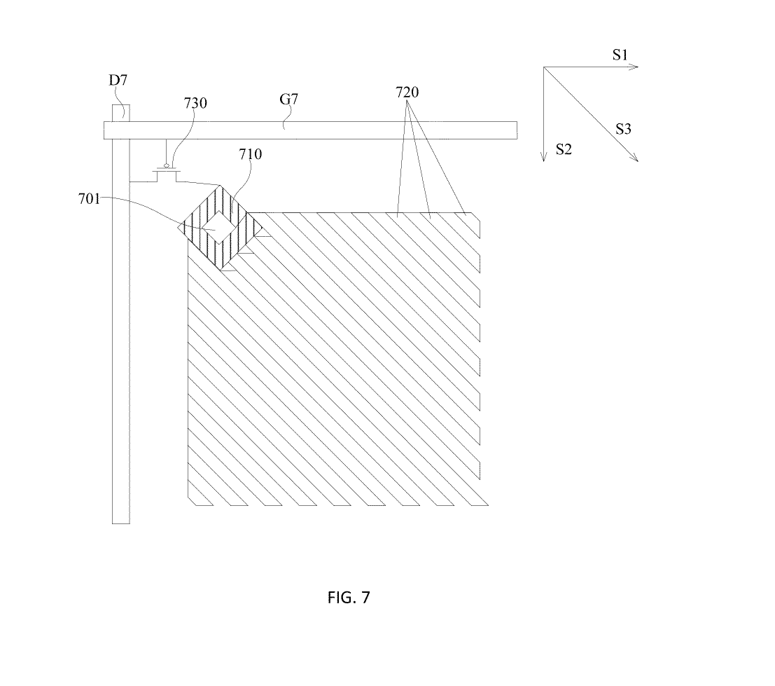

With reference to FIG. 7, it is a schematic drawing of a pixel unit according to a second embodiment of the present invention. A pixel unit includes a scan line G7, a data line D7, a solder pad 710, an insulation layer (not shown), multiple strip electrodes 720 and a thin film transistor 730.

The scan line G7 extends along a first extension direction S1. The data line D7 extends along a second extension direction S2. The first extension direction S1 is intersected with the second extension direction S2.

The solder pad 710 is formed on the intersection location of the scan line G7 and the data line D7. The solder pad 710 electrically connects to the scan line G7 and the data line D7, for example, by wire connections. The insulation layer covers the scan line G7, the data line D7, and the solder pad 710, and the insulation layer has a through hole 701.

The multiple strip electrodes 720 are parallel with each other and spaced apart, and strip electrodes 720 disposed on the insulation layer and extend along the third extension direction S3. The third extension direction S3 and the first extension direction S1 form a predetermined angle. The multiple strip electrodes 720 are electrically connected to the solder pad 710 by the through hole 701.

The thin film transistor 730 is located at the intersection location of the scan line G7 and the data line D7, and a gate electrode of the thin film transistor 730 is electrically connected to the scan line G7, a source electrode is electrically connected to the data line D7, and a drain electrode electrically connected to the solder pad 710.

The solder pad 710 and the strip electrodes 720 are all made of a transparent conductive material, the shape of the solder pad 710 is a polygon, and at least one side of the solder pad 710 is parallel to the third extension direction S3. Because the at least one side of the solder pad 710 is parallel to the strip electrodes 720, a direction of the electric field near the side of the solder pad 710 is the same with a direction of the electric field of the strip electrodes 720. Therefore, the affect suffering by the electric field of the strip electrodes 720 is reduced to effectively suppress the “dark fringes” phenomenon.

The difference between this embodiment and the first embodiment is that the pixel unit is utilizing an active drive method. The thin film transistor 730 functions as an active switching element so as to control the connection between the strip electrodes 720 and the data line D7 in order to control the arrangement of the liquid crystal molecules.

The present invention also provides an array substrate, and the array substrate can be utilized in the LCD device. The array substrate includes a glass substrate and the pixel unit described at the foregoing embodiments. The pixel unit is disposed on the glass substrate. Other structural of the array substrate can refer to the existing technology, and it is not mentioned here.

Through the above way, in the pixel unit and the array substrate of the present invention, at least one side of the solder pad is parallel to the extension direction of the strip electrodes so that the at least one side of the solder pad does not affect the electric field of at least one side of the field strip electrodes. The impact of the electric field of the strip electrodes can be reduced so as to effectively suppress the “dark fringes” phenomenon around the solder pad and to enhance the display quality.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

1. A pixel unit comprising:
a scan line extended along a first extension direction;
a data line extended along a second extension direction, wherein, the first extension direction is intersected with the second extension direction;
a solder pad formed at an intersection location of the scan line and the data line, and the solder pad electrically connects to the scan line and the data line;
an insulation layer covering the scan line and the data line, and having a through hole; and
multiple strip electrodes parallel with each other and spaced apart, and disposed on the insulation layer and extending along a third extension direction, wherein, the third extension direction and the first extension direction form a predetermined angle, and the multiple strip electrodes electrically connect to the solder pad by the through hole;
wherein, the solder pad and the multiple strip electrodes are all made of a transparent conductive material; a shape of the solder pad is a quadrilateral with at least a pair of parallel opposite sides; the at least a pair of parallel opposite sides of the solder pad is parallel to the third extension direction; a shape of the through hole is a quadrilateral with at least a pair of parallel opposite sides; the at least a pair of parallel opposite sides of the through hole is parallel to the third extension direction; the first extension direction and the second extension direction are perpendicular.

2. The pixel unit according to claim 1, wherein, the pixel unit further comprises a thin film transistor, wherein, the thin film transistor located at the intersection location of the scan line and the data line, and a gate electrode of the thin film transistor is electrically connected to the scan line, a source electrode is electrically connected to the data line, and a drain electrode is electrically connected to the solder pad.

3. The pixel unit according to claim 1, wherein, the predetermined angle is 45 degrees.

4. The pixel unit according to claim 1, wherein, the transparent conductive material is indium tin oxide.

5. The pixel unit according to claim 1, wherein, the multiple strip electrodes are spaced apart with the same spacing.

6. A pixel unit comprising:
a scan line extended along a first extension direction;
a data line extended along a second extension direction, wherein, the first extension direction is intersected with the second extension direction;
a solder pad formed at an intersection location of the scan line and the data line, and the solder pad electrically connects to the scan line and the data line;
an insulation layer covering the scan line and the data line, and having a through hole; and
multiple strip electrodes parallel with each other and spaced apart, and disposed on the insulation layer and extending along a third extension direction, wherein, the third extension direction and the first extension direction form a predetermined angle, and the multiple strip electrodes electrically connect to the solder pad by the through hole;
wherein, the solder pad and the multiple strip electrodes are all made of a transparent conductive material; a shape of the solder pad is a polygon; at least one side of the solder pad is parallel to the third extension direction.

7. The pixel unit according to claim 6, wherein, the pixel unit further comprises a thin film transistor, wherein, the thin film transistor located at the intersection location of the scan line and the data line, and a gate electrode of the thin film transistor is electrically connected to the scan line, a source electrode is electrically connected to the data line, and a drain electrode is electrically connected to the solder pad.

8. The pixel unit according to claim 6, wherein, the shape of the solder pad is a quadrilateral with at least a pair of parallel opposite sides, and the at least a pair of parallel opposite sides of the solder pad is parallel to the third extension direction.

9. The pixel unit according to claim 8, wherein, a shape of the through hole is a polygon; at least one side of the through hole is parallel to the third extension direction.

10. The pixel unit according to claim 9, wherein, the shape of the through hole is a quadrilateral with at least a pair of parallel opposite sides, and the at least a pair of parallel opposite sides of the through hole is parallel to the third extension direction.

11. The pixel unit according to claim 6, wherein, the first extension direction and the second extension direction are perpendicular.

12. The pixel unit according to claim 11, wherein, the predetermined angle is 45 degrees.

13. The pixel unit according to claim 6, wherein, the transparent conductive material is indium tin oxide.

14. The pixel unit according to claim 6, wherein, the multiple strip electrodes are spaced apart with the same spacing.

15. An array substrate comprising:
a glass substrate; and
a pixel unit disposed on the glass substrate, the pixel unit comprising:
a scan line extended along a first extension direction;
a data line extended along a second extension direction, wherein, the first extension direction is intersected with the second extension direction;
a solder pad formed at an intersection location of the scan line and the data line, and the solder pad electrically connects to the scan line and the data line;
an insulation layer covering the scan line and the data line, and having a through hole; and
multiple strip electrodes parallel with each other and spaced apart, and disposed on the insulation layer and extending along a third extension direction, wherein, the third extension direction and the first extension direction form a predetermined angle, and the multiple strip electrodes electrically connect to the solder pad by the through hole;
wherein, the solder pad and the multiple strip electrodes are all made of a transparent conductive material; a shape of the solder pad is a polygon; at least one side of the solder pad is parallel to the third extension direction.

16. The array substrate according to claim 15, wherein, the pixel unit further comprises a thin film transistor, wherein, the thin film transistor located at the intersection location of the scan line and the data line, and a gate electrode of the thin film transistor is electrically connected to the scan line, a source electrode is electrically connected to the data line, and a drain electrode is electrically connected to the solder pad.

17. The array substrate according to claim 15, wherein, the shape of the solder pad is a quadrilateral with at least a pair of parallel opposite sides, and the at least a pair of parallel opposite sides of the solder pad is parallel to the third extension direction.

18. The array substrate according to claim 17, wherein, a shape of the through hole is a polygon; at least one side of the through hole is parallel to the third extension direction.

19. The array substrate according to claim 18, wherein, the shape of the through hole is a quadrilateral with at least a pair of parallel opposite sides, and the at least a pair of parallel opposite sides of the through hole is parallel to the third extension direction.

20. The array substrate according to claim 15, wherein, the first extension direction and the second extension direction are perpendicular.
